(19) United States
(12) Patent Application Publication
(10) Pub. No.: US 2011/0140764 A1
(43) Pub. Date: Jun. 16, 2011

(54) CMOS SWITCH FOR USE IN RADIO FREQUENCY SWITCHING AND ISOLATION ENHANCEMENT METHOD

(75) Inventors: Dong Hwan Shin, Daejeon (KR); In Bok Yom, Daejeon (KR)

(73) Assignee: Electronics & Telecommunications Research, Daejeon (KR)

(21) Appl. No.: 12/771,567

(22) Filed: Apr. 30, 2010

(30) Foreign Application Priority Data
Dec. 16, 2009 (KR) 10-2009-0125605

(51) Int. Cl. H03K 17/687

(52) U.S. Cl. 327/437

(57) ABSTRACT

Provided is a CMOS switch for use in RF switching having improved isolation properties. The CMOS switch includes a serial switching unit having first and second CMOS switches, a switching isolation unit for allowing an unselected output terminal of two output terminals to be electrically isolated from a common input terminal when the serial switching unit operates and an isolation enhancement unit. The isolation enhancement unit is connected in parallel to the first and the second CMOS switches between the two output terminals forming a parallel resonance circuit together with a parasitic capacitor of the serial switching unit. The CMOS switch for use in RF switching according to the present invention has a simple circuit structure and excellent operating properties at the MF or higher band. Also, the CMOS switch having high isolation properties is realized.

### CROSS-REFERENCE TO RELATED APPLICATIONS

This U.S. non-provisional patent application claims priority under 35 U.S.C. §119 of Korean Patent Application No. 10-2009-0125605, filed on Dec. 16, 2009, the entire contents of which are hereby incorporated by reference.

### BACKGROUND OF THE INVENTION

The present invention disclosed herein relates to a switch used for controlling the path of a Radio Frequency (RF) signal in a Microwave Frequency (MF) component and system, and more particularly, to a Complementary Metal Oxide Semiconductor (CMOS) switch operating in the RF band such as the MF band.

The development of the Integrated Circuit (IC) technology has greatly contributed to the advancement of the wireless communication industry over the decades. Due to the development of the wireless communication industry, RF components such as low-noise amplifiers, oscillators, high-output amplifiers and switches, which are fabricated using the IC technology, particularly the CMOS technology, are being used in various application fields such as mobile phones and wireless Local Area Networks (LANs). With the development of the wireless communication industry, operational frequency bands are increasing and RF components, which use the CMOS technology, are being required to operate at a higher frequency band than the X band.

FIG. 1 is a circuit diagram of a typical CMOS-type Single Pole Double Through (SPDT) switch using the typical CMOS technology.

Referring to FIG. 1, the CMOS SPDT switch includes a serial switching unit and a switching isolation unit. The serial switching unit includes first and second CMOS switches 104 and 105. The switching isolation unit includes N-type MOS transistors 106 and 107. The switching isolation unit lets an unselected output terminal between first and second output terminals 102 and 103 be electrically isolated from a common input terminal 101 when the serial switching unit operates.

The first and the second CMOS switches 104 and 105 used as switching elements for the common input terminal 101 are respectively coupled to the first output terminal 102 and the second output terminal 103. According to voltage levels supplied to first and second control terminals 108 and 109, a switching path is formed between the common terminal 101 and the first output terminal 102 or between the common terminal 101 and the second output terminal 103. For instance, when a switch-on voltage is applied to the first control terminal 108 and a switch-off voltage is applied to the second control terminal 109, the first CMOS switch 104 and the second CMOS switch 105 coupled to the common input terminal 101 are respectively turned on and off. Also, in this case, the N-type MOS transistor 106 coupled to the first output terminal 102 is turned off and the N-type MOS transistor 107 coupled to the second output terminal 103 is turned on. Accordingly, an RF signal applied to the common input terminal 101 is switched through the first CMOS switch 104 and outputted to the first output terminal 102. Herein, the N-type MOS transistors 106 and 107, which are connected in parallel to the first output terminal 102 and the second output terminal 103 respectively, are shut elements for increasing the isolation of the switch circuit.

Since the CMOS element is used as the switching element for the above-mentioned switch, the switching control is relatively easy and power is little consumed. However, as the operating frequency of the signal increases, the insertion loss increases, and particularly the isolation properties of the switch are degraded due to a parasitic capacitance.

FIG. 2 is a schematic circuit diagram and its equivalent circuit diagram of the CMOS switch shown in FIG. 1 illustrating the CMOS element and its equivalent circuit used as the switching element for the RF and the MF bands.

Referring to FIG. 2, there are a MOS transistor 204 which switches on or off a connection between a first terminal 202 and a second terminal 203 according to a voltage level applied to a control terminal 201 and a resistor RG equivalently corresponding to one of the first and the second CMOS switches 104 and 105. As shown in the equivalent circuit diagram, the on/off operation of the MOS transistor 204 may be represented by a size change of a variable resistor 204. Also, since there remains the parasitic capacitance in the CMOS switching element, there equivalently exist a capacitor 205 and a junction capacitance at a diode 206. As the frequency increases, such a parasitic capacitance element more affects the switching operation causing decrease of the switching isolation in the RF and the MF bands.

### SUMMARY OF THE INVENTION

Embodiments of the present invention provide a CMOS switch which has improved isolation properties, and a method for enhancing a switching isolation.

Embodiments of the present invention also provide a CMOS switch for use in RF switching which is simply structured and has excellent operating properties at the MF or higher band.

Embodiments of the present invention also provide a CMOS switch for use in RF switching capable of substantially preventing a leakage current at a switching operation.

In some embodiments of the present invention, CMOS switches for use in RF switching include: a serial switching unit including first and second CMOS switches and constructing an SPDT switch; a switching isolation unit for allowing an unselected output terminal of two output terminals to be electrically isolated from a common input terminal when the serial switching unit operates; and an isolation enhancement unit connected in parallel to the first and the second CMOS switches between the two output terminals, and enhancing a switching isolation of the serial switching unit by forming a parallel resonance circuit together with a parasitic capacitor of the serial switching unit.

In some embodiments, the SPDT switch may switch a signal of an MF band. The isolation enhancement unit may include an inductor which has a reasonable inductance for forming an LC parallel resonance circuit corresponding to a parasitic capacitance of the parasitic capacitor.

In other embodiments, the switching isolation unit may include first and second shunt elements respectively connected to the two output terminal in parallel with the first and the second CMOS switches. Each of the first and the second shunt elements may include an NMOS transistor.

In other embodiments of the present invention, CMOS switches for use in RF switching include: a serial switching unit including first and second CMOS switches connected between two output terminals and constructing a SPDT switch; a switching isolation unit for allowing an unselected output terminal of the two output terminals to be electrically isolated from a common input terminal when the serial switching unit operates; a first isolation enhancement unit connected in parallel to the first and the second CMOS switches between the two output terminals, and enhancing a switching isolation of the serial switching unit by forming a parallel resonance circuit with a parasitic capacitor of the serial switching unit; and a second isolation enhancement unit connected between the common input terminal and a ground, and enhancing the switching isolation and input matching properties of the serial switching unit.

In some embodiments, the first isolation enhancement unit may include an inductor which has a reasonable inductance for forming an LC parallel resonance circuit corresponding to a parasitic capacitance of the parasitic capacitor.

In other embodiments, the second isolation enhancement unit may include an inductor which has an inductance for enhancing the switching isolation and input matching properties.

In still other embodiments of the present invention, CMOS switches for use in RF switching include: a serial switching unit including a first CMOS switch and a second output terminal, wherein, the first CMOS switch is connected between a common input terminal and a first output terminal for switching the common input terminal to the first output terminal in response to a first control signal, and the second CMOS switch is connected between the common input terminal and a second output terminal for switching the common input terminal to the second output terminal in response to a second control signal; a switching isolation unit including a first shunt element and a second shunt element, wherein the first shunt element allows the second output terminal to be electrically isolated from the common input terminal in response to the first control signal when the first CMOS switch operates, and the second shunt element allows the first output terminal to be electrically isolated from the common input terminal in response to the second control signal when the second CMOS switch operates; and an isolation enhancement unit connected in parallel to the first and the second CMOS switches between the first and the second output terminals, and enhancing a switching isolation of the serial switching unit by forming a parallel resonance circuit together with a parasitic capacitor of the serial switching unit.

In some embodiments, each of the first and the second CMOS switches may include an NMOS transistor. Each of the first and the second shunt elements may include an NMOS transistor. The isolation enhancement unit may include an inductor.

In even other embodiments of the present invention, CMOS switches for use in RF switching include: a serial switching unit including a first CMOS switch and a second CMOS switch, wherein the first CMOS switch is connected between a common input terminal and a first output terminal for switching the common input terminal to the first output terminal in response to a first control signal, and the second CMOS switch is connected between the common input terminal and a second output terminal for switching the common input terminal to the second output terminal in response to a second control signal; a switching isolation unit including a first shunt element and a second shunt element, wherein the first shunt element allows the second output terminal to be electrically isolated from the common input terminal in response to the first control signal when the first CMOS switch operates, and the second shunt element allows the first output terminal to be electrically isolated from the common input terminal in response to the second control signal when the second CMOS switch operates; a first isolation enhancement unit connected in parallel to the first and the second CMOS switches between the first and the second output terminals, and enhancing a switching isolation of the serial switching unit by forming a parallel resonance circuit together with a parasitic capacitor of the serial switching unit; and a second isolation enhancement unit connected between the common input terminal and a ground enhancing the switching isolation and input matching properties of the serial switching unit.

In some embodiments, each of the first and the second CMOS switches and the first and the second shunt elements may include an NMOS transistor. Each of the first and the second isolation enhancement unit may include an inductor.

In yet other embodiments of the present invention, a method for enhancing a switching isolation in an SPDT switch including a serial switching unit having first and second CMOS switches and a switching isolation unit electrically isolating an unselected output terminal between two output terminals from a common input terminal when the serial switching unit operates, the method includes: operating one of the first and the second CMOS switches in response to a control signal; and forming an LC parallel resonance circuit with a parasitic capacitor of the serial switching unit when the serial switching unit operates.

In some embodiments, the LC parallel resonance circuit may be formed by including an inductor connected in parallel with the first and the second CMOS switches.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a circuit diagram of a typical CMOS-type SPDT switch using the typical CMOS technology;

FIG. 2 is a schematic circuit diagram and its equivalent circuit diagram of the CMOS switch shown in FIG. 1;

FIG. 3 is a circuit diagram of a CMOS switch for use in RF switching according to a first embodiment of the present invention;

FIG. 4 is a circuit diagram of a CMOS switch for use in RF switching according to the second embodiment of the present invention;

FIG. 5 is a simulation graph illustrating the properties of the switch of FIG. 1; and

FIG. 6 is a simulation graph illustrating the properties of the switch of FIG. 3.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

It will be understood that when an element or line is referred to as being connected to a target element, it may be connected directly to the target element or may be connected indirectly to the target element through another element.

It will also be understood that like reference numerals refer to like elements throughout.

It will also be understood that an embodiment described and exemplified herein includes a complementary embodiment thereof.

Hereinafter, it will be described about an exemplary embodiment of the present invention in conjunction with the accompanying drawings.

FIG. 3 is a circuit diagram of a CMOS switch for use in RF switching according to a first embodiment of the present invention.

It will be explained that the switching isolation properties are improved by connecting an inductor element in parallel to a switching element in the case of the first embodiment illustrated in FIG. 3. FIG. 3 illustrates an exemplary embodiment of a CMOS RF switch, and it will be understood that the embodiment may be suitable for a CMOS SPDT switch used in an MF band. The CMOS RF switch may be fabricated by using various semiconductor manufacturing processes including, e.g., a 0.25 μm process.

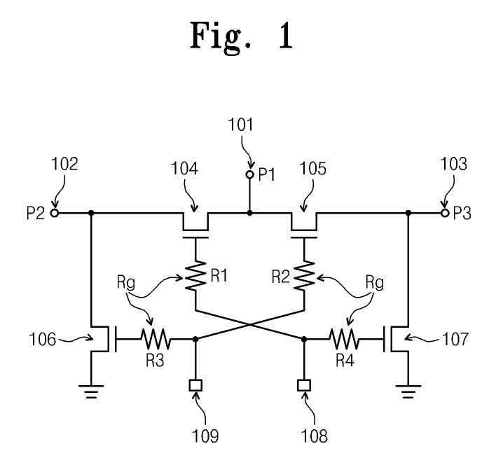

Referring to FIG. 3, unlike FIG. 1, an isolation enhancement unit 310 is connected in parallel to first and second CMOS switches 304 and 305 between first and second output terminals P2 and P3. The isolation enhancement unit 310, which may be embodied with an inductor L1, forms a parallel resonance circuit with a parasitic capacitor generated due to the first and the second CMOS switches 304 and 305, thereby more enhancing the switching isolation.

Like FIG. 1, in FIG. 3, a serial switching unit includes the first and the second CMOS switches 304 and 305 forming a SPDT switch, and N-type MOS transistors 306 and 307 serve as a switching isolation unit for an unselected output terminal between the first and the second output terminals P2 and P3 to be electrically isolated from a common input terminal P1 when the serial switching unit operates.

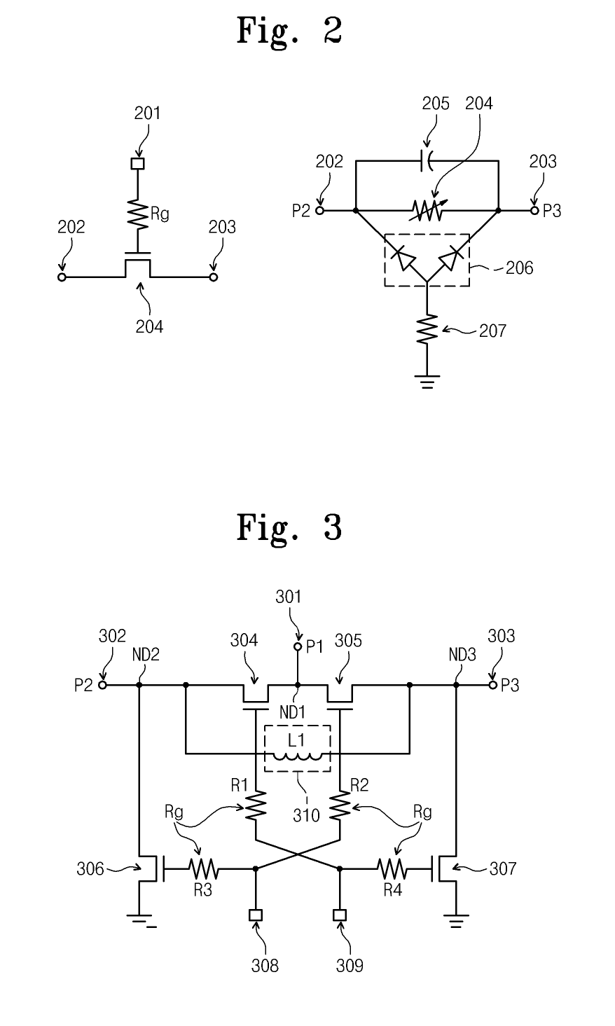

As above-described referring to FIG. 2, the switching properties of such a switch circuit shown in FIG. 1 are degraded due to the parasitic capacitance of the CMOS switch. In order to solve this matter, the inductor L1 is included for forming an LC parallel resonance circuit with the parasitic capacitance as shown in FIG. 3. As a result, if an inductance of the inductor L1 and the parasitic capacitance are combined and form the parallel resonance circuit, a signal leakage of the unselected output terminal (P3, in the case where an RF signal is switched to the output terminal P2) is prevented or minimized by an LC parallel resonance operation.

A value of the inductance of the inductor L1 is appropriately determined based on the parasitic capacitance due to the first and the second CMOS switches 304 and 305 in order to induce a parallel resonance at a desired band.

A basic operation of the CMOS switch for use in RF switching shown in FIG. 3 is similar to the operation above-described referring to FIG. 1.

For instance, when a switch-on voltage is applied to a first control terminal 309 and a switch-off voltage is applied to a second control terminal 308, the first and the second CMOS switches connected to the common input terminal P1 are respectively turned on and off. Also, in this case, the N-type MOS transistor 306 connected to the first output terminal P2 is turned off and the N-type MOS transistor 307 connected to the second output terminal P3 is turned on. Accordingly, the RF signal applied to the common input terminal P1 is switched through the first CMOS switch 304 and outputted to the first output terminal P2. At this switching operation, the N-type MOS transistor 307 performs a shunt operation for increasing the isolation of the switch circuit by making a voltage level of a node ND3 become a ground level, and the inductor L1 of the isolation enhancement unit 310 forms a parallel resonance circuit together with the parasitic capacitor of the serial switch and performs the LC parallel resonance operation.

Accordingly, the RF signal is completely transferred to the selected output terminal (i.e., P2) and a signal leakage at the unselected output terminal (i.e., P3) is completely prevented or minimized.

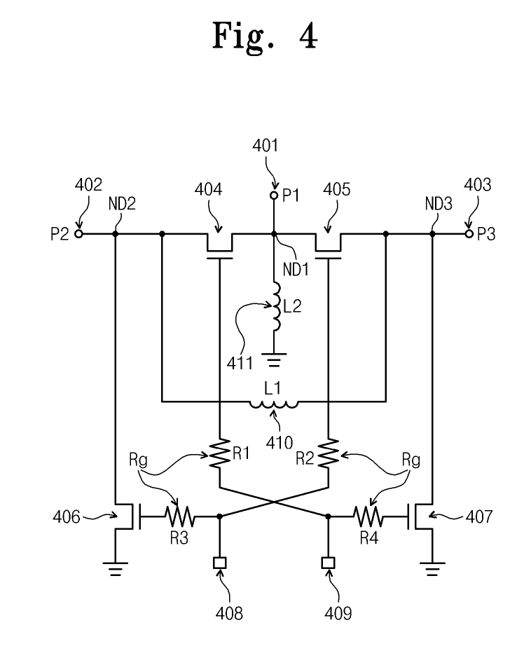

A second embodiment will now be described referring to FIG. 4.

FIG. 4 is a circuit diagram of a CMOS switch for use in RF switching according to the second embodiment of the present invention.

Referring to FIG. 4, a serial switching unit includes a first CMOS switch 404 and a second CMOS switch 405. The first CMOS switch 404 is connected between a common input terminal 401 and a first output terminal 402. The first CMOS switch 404 switches the common input terminal 401 to the first output terminal 402 in response to a first control signal applied to a first control terminal 409. The second CMOS switch 405 is connected between the common input terminal 401 and a second output terminal 403. The second CMOS switch 405 switches the common input terminal 401 to the second output terminal 403 in response to a second control signal applied to a second control terminal 408.

A switching isolation unit includes a first shunt element 407 and a second shunt element 406. The first shunt element 407 serves to allow the second output terminal 403 to be electrically isolated from the common input terminal 401 in response to the first control signal when the first CMOS switch 404 operates. The second shunt element 406 serves to allow the first output terminal 402 to be electrically isolated from the common input terminal 401 in response to the second control signal when the second CMOS switch 405 operates.

A first isolation enhancement unit 410 formed with an inductor L1 is connected in parallel to the first and the second CMOS switches 404 and 405 between the first and the second output terminals 402 and 403. The first isolation enhancement unit 410 enhances the switching isolation of the serial switching unit by forming a parallel resonance circuit together with a parasitic capacitor of the serial switching unit.

A second isolation enhancement unit 411 formed with an inductor L2 is connected between a connection node ND1 of the common input terminal 401 and a ground, and serves to enhance the switching isolation and input matching properties of the serial switching unit.

The circuit structure of FIG. 4 additionally includes the inductor L2 between the common input terminal 401 and the ground in comparison with that of FIG. 3. Due to this added inductor L2, the isolation properties and the input matching properties are improved. Accordingly, the reflection loss and the insertion loss at the switching operation of the switch are improved in comparison with a typical switch. Since the circuit of FIG. 4 has a size burden in comparison with that of FIG. 3, it may be considered to appropriately adopt the circuit in the case where the size burden is not relatively serious.

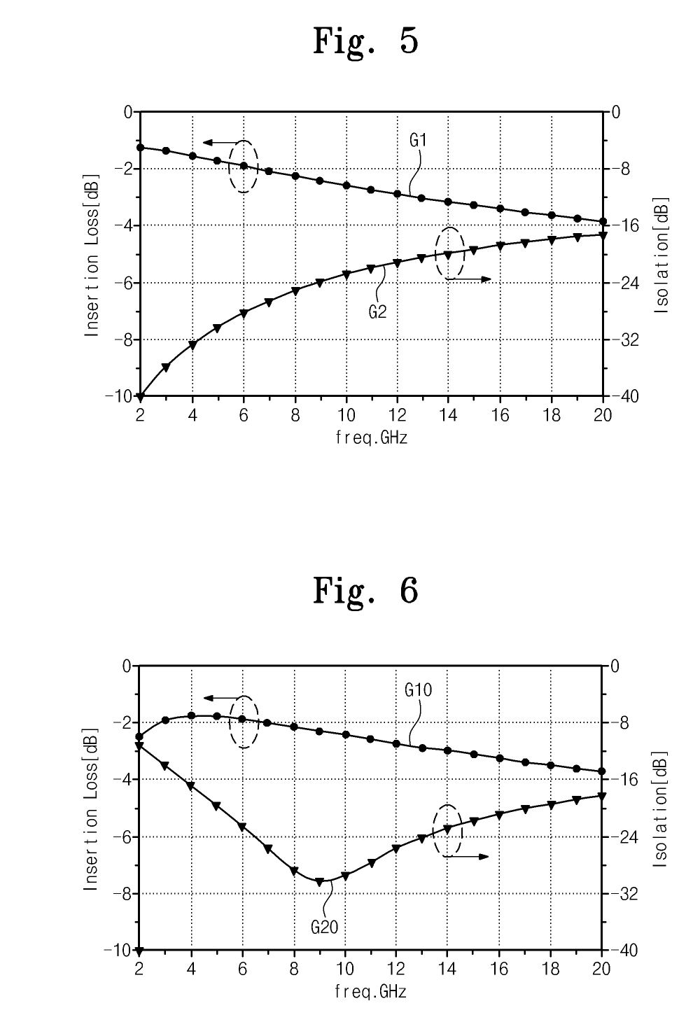

FIG. 5 is a simulation graph illustrating the properties of the switch according to FIG. 1, and FIG. 6 is a simulation graph illustrating the properties of the switch according to FIG. 3.

In FIGS. 5 and 6, the horizontal axis, the left side of the vertical axis and the right side of the vertical axis respectively represent the frequency (GHz), the insertion loss (dB) and the isolation (dB).

As shown at a graph G2 in FIG. 5, the switch of FIG. 1 has good isolation properties at relatively low frequencies lower than 2 GHz; however, the isolation properties become worse as the frequency increases. As a result, the isolation is represented as a value of about 23 dB at the X band, i.e., 10 GHz. Also, a graph G1 shows the insertion loss at each frequency. As shown in FIG. 5, a typical CMOS SPDT switch such as that of FIG. 1 has poor isolation properties at the X band, i.e., 10 GHz.

Meanwhile, referring to a graph G20 of FIG. 6, the isolation properties have been remarkably improved in the case of the switch of FIG. 3 in comparison with that of FIG. 1. The isolation properties according to the first embodiment of the present invention are represented as a value of about 30 dB at the X band, i.e., 10 GHz. Accordingly, the isolation properties of the circuit of FIG. 3 have been improved by about 7 dB (30 dB-23 dB) in comparison with that of FIG. 1. Also, comparing a graph G10 with the graph G1 of FIG. 5, it can be ascertained that the insertion loss has also been improved.

The switch according to the embodiments of the present invention may be applied to RF components such as low-noise amplifiers, oscillators, high-output amplifiers and switches fabricated using the CMOS technology. Since such a switch has excellent insertion loss properties at the RF band, it may be more useful in the fields where signals having higher frequencies than the X band such as the MF band are switched.

According to the embodiments of the present invention of the CMOS switch for use in RF switching, a CMOS switch which has improved isolation properties can be embodied. The CMOS switch for use in RF switching according to the present invention has a simple circuit structure and excellent operating properties at the MF or higher band. Also, a CMOS switch which has high isolation properties is embodied.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A Complementary Metal Oxide Semiconductor (CMOS) switch for use in Radio Frequency (RF) switching, comprising:
a serial switching unit including first and second CMOS switches and forming a Single Pole Double Through (SPDT) switch;
a switching isolation unit for allowing an unselected output terminal of two output terminals to be electrically isolated from a common input terminal when the serial switching unit operates; and
an isolation enhancement unit connected in parallel to the first and the second CMOS switches between the two output terminals, for enhancing a switching isolation of the serial switching unit by forming a parallel resonance circuit together with a parasitic capacitor of the serial switching unit.

2. The CMOS switch of claim 1, wherein the SPDT switch switches a signal of a Microwave Frequency (MF) band.

3. The CMOS switch of claim 1, wherein the isolation enhancement unit comprises an inductor which has a reasonable inductance for forming an LC parallel resonance circuit corresponding to a parasitic capacitance of the parasitic capacitor.

4. The CMOS switch of claim 1, wherein the switching isolation unit comprises first and second shunt elements respectively connected to the two output terminal in parallel with the first and the second CMOS switches.

5. The CMOS switch of claim 4, wherein each of the first and the second shunt elements comprises an N-type Metal Oxide Semiconductor (NMOS) transistor.

6. A CMOS switch for use in RF switching, comprising:
a serial switching unit including first and second CMOS switches connected between two output terminals and constructing a SPDT switch;
a switching isolation unit for allowing an unselected output terminal of the two output terminals to be electrically isolated from a common input terminal when the serial switching unit operates;
a first isolation enhancement unit connected in parallel to the first and the second CMOS switches between the two output terminals, and enhancing a switching isolation of the serial switching unit by forming a parallel resonance circuit together with a parasitic capacitor of the serial switching unit; and
a second isolation enhancement unit connected between the common input terminal and a ground, and enhancing the switching isolation and input matching properties of the serial switching unit.

7. The CMOS switch of claim 6, wherein the first isolation enhancement unit comprises an inductor which has a reasonable inductance for forming an LC parallel resonance circuit corresponding to a parasitic capacitance of the parasitic capacitor.

8. The CMOS switch of claim 6, wherein the second isolation enhancement unit comprises an inductor which has an inductance for enhancing the switching isolation and input matching properties.

9. The CMOS switch of claim 6, wherein the switching isolation unit comprises first and second shunt elements respectively connected to the two output terminal in parallel with the first and the second CMOS switches.

10. The CMOS switch of claim 9, wherein each of the first and the second shunt elements comprises an NMOS transistor.

11. The CMOS switch of claim 10, wherein the SPDT switch is an NMOS transistor type switch which switches a signal of an MF band.

12. A CMOS switch for use in RF switching, comprising:
a serial switching unit including a first CMOS switch and a second output terminal, wherein the first CMOS switch is connected between a common input terminal and a first output terminal for switching the common input terminal to the first output terminal in response to a first control signal, and the second CMOS switch is connected between the common input terminal and a second output terminal for switching the common input terminal to the second output terminal in response to a second control signal;
a switching isolation unit including a first shunt element and a second shunt element, wherein the first shunt element allows the second output terminal to be electrically isolated from the common input terminal in response to the first control signal when the first CMOS switch operates, and the second shunt element allows the first output terminal to be electrically isolated from the common input terminal in response to the second control signal when the second CMOS switch operates; and
an isolation enhancement unit connected in parallel to the first and the second CMOS switches between the first and the second output terminals, and enhancing a switching isolation of the serial switching unit by forming a parallel resonance circuit together with a parasitic capacitor of the serial switching unit.

13. The CMOS switch of claim 12, wherein each of the first and the second CMOS switches comprises an NMOS transistor.

14. The CMOS switch of claim 13, wherein each of the first and the second shunt elements comprises an NMOS transistor.

15. The CMOS switch of claim 14, wherein the isolation enhancement unit comprises an inductor.

16. A CMOS switch for use in RF switching, comprising:
a serial switching unit including a first CMOS switch and a second CMOS switch, wherein the first CMOS switch is connected between a common input terminal and a first output terminal for switching the common input terminal to the first output terminal in response to a first control signal, and the second CMOS switch is connected between the common input terminal and a second output terminal for switching the common input terminal to the second output terminal in response to a second control signal;
a switching isolation unit including a first shunt element and a second shunt element, wherein the first shunt element allows the second output terminal to be electrically isolated from the common input terminal in response to the first control signal when the first CMOS switch operates, and the second shunt element allows the first output terminal to be electrically isolated from the common input terminal in response to the second control signal when the second CMOS switch operates;
a first isolation enhancement unit connected in parallel to the first and the second CMOS switches between the first and the second output terminals, and enhancing a switching isolation of the serial switching unit by forming a parallel resonance circuit together with a parasitic capacitor of the serial switching unit; and
a second isolation enhancement unit connected between the common input terminal and a ground enhancing the switching isolation and input matching properties of the serial switching unit.

17. The CMOS switch of claim 16, wherein each of the first and the second CMOS switches comprises an NMOS transistor.

18. The CMOS switch of claim 17, wherein each of the first and the second shunt elements comprises an NMOS transistor.

19. The CMOS switch of claim 18, wherein each of the first and the second isolation enhancement unit comprises an inductor.

20. A method for enhancing a switching isolation in an SPDT switch including a serial switching unit having first and second CMOS switches and a switching isolation unit electrically isolating an unselected output terminal between two output terminals from a common input terminal when the serial switching unit operates, the method comprising:
operating one of the first and the second CMOS switches in response to a control signal; and
forming an LC parallel resonance circuit together with a parasitic capacitor of the serial switching unit when the serial switching unit operates.
